(19) United States
(12) Patent Application Publication
(10) Pub. No.: US 2015/0177620 A1
(43) Pub. Date: Jun. 25, 2015

(54) CONDUCTIVE LAYER MANUFACTURING METHOD AND PRINTED CIRCUIT BOARD

(71) Applicant: FUJIFILM Corporation, Tokyo (JP)

(72) Inventor: Hiroshi OHTA, Ashigara-kami-gun (JP)

(73) Assignee: FUJIFILM CORPORATION, Tokyo (JP)

(21) Appl. No.: 14/642,488

(22) Filed: Mar. 9, 2015

Related U.S. Application Data
(63) Continuation of application No. PCT/JP2013/071944, filed on Aug. 15, 2013.

(30) Foreign Application Priority Data
Sep. 14, 2012 (JP) 2012-202421

(51) Int. Cl. G03F 7/20

(52) U.S. Cl. CPC G03F 7/20

(57) ABSTRACT

In a conductive layer manufacturing method, there is provided a reducing step of irradiating with light a precursor layer-carrying support having a support and a copper oxide particle-containing precursor layer provided on the support so as to reduce copper oxide particles contained in the precursor layer to thereby form a metallic copper-containing conductive layer, and a filling ratio of the copper oxide particles in the precursor layer is at least 65%.

### CROSS-REFERENCE TO RELATED APPLICATIONS

This application is a Continuation of PCT International Application No. PCT/JP2013/071944 filed on Aug. 15, 2013, which claims priority under 35 U.S.C. §119(a) to Japanese Application No. 2012-202421 filed on Sep. 14, 2012. Each of the above application(s) is hereby expressly incorporated by reference, in its entirety, into the present application.

### BACKGROUND OF THE INVENTION

The present invention relates to a conductive layer manufacturing method, particularly to a method for manufacturing a conductive layer by irradiating with light a copper oxide particle-containing layer having a predetermined filling ratio. In addition, the present invention relates to a printed circuit board having the conductive layer manufactured by the conductive layer manufacturing method.

As a method for forming a metal layer on a substrate, there is known a technique of forming electrically conductive parts such as a metal layer and interconnects in a circuit board by applying a metal particle or metal oxide particle dispersion onto a substrate by a printing method, followed by irradiation with light for sintering.

High expectations are placed on the method above in the field of next generation electronics development because this is a simple, energy-saving and resource-saving method compared to conventional interconnect fabricating methods using a high temperature vacuum process (sputtering) or plating.

To be more specific, JP 2010-528428 A discloses a method in which a film containing a plurality of copper oxide nanoparticles is deposited on a surface of a substrate, and at least a part of the film is exposed to light to be conductive.

### SUMMARY OF THE INVENTION

Meanwhile, in recent years, there is a demand for further improvement in performance of a product having a circuit board and the like and accordingly, further enhancement in conductive properties of a conductive layer as formed using a composition including copper oxide particles is required.

The present inventor has formed a conductive layer by the method described in JP 2010-528428 A and found that the obtained conductive layer does not have the conductivity at the presently required level and therefore needs further improvement.

In view of the above, an object of the present invention is to provide a conductive layer manufacturing method that enables the manufacture of a conductive layer having excellent conductivity.

The present inventor has made an intensive study on the problem of the related art and as a result found that the problem can be solved by controlling the filling ratio of copper oxide particles in a copper oxide particle-containing precursor layer to be subjected to light irradiation treatment.

Specifically, the inventor found that the object can be achieved by the characteristic features described below.

(1) A conductive layer manufacturing method comprising a reducing step of irradiating with light a precursor layer-carrying support having a support and a copper oxide particle-containing precursor layer provided on the support so as to reduce copper oxide particles contained in the precursor layer to thereby form a metallic copper-containing conductive layer, wherein a filling ratio of the copper oxide particles in the precursor layer is at least 65%.
(2) The conductive layer manufacturing method according to (1) wherein the support is a porous layer-carrying substrate having a substrate and a porous layer provided on the substrate, and wherein the reducing step is preceded by a precursor layer forming step of forming the precursor layer by applying a copper oxide particle-containing solution onto the porous layer-carrying substrate.
(3) The conductive layer manufacturing method according to (2), wherein the porous layer has an average pore size smaller than an average particle size of the copper oxide particles.
(4) The conductive layer manufacturing method according to (2) or (3), wherein materials making up the porous layer include at least one selected from the group consisting of silica and zirconia.
(5) The conductive layer manufacturing method according to any one of (2) to (4), wherein the porous layer has a porosity of 50 to 80%.
(6) The conductive layer manufacturing method according to any one of (2) to (5), wherein the porous layer has an average pore size of 5 to 20 nm.
(7) The conductive layer manufacturing method according to any one of (2) to (6), wherein the porous layer has a thermal conductivity lower than that of the precursor layer.
(8) A printed circuit board having a conductive layer manufactured by the conductive layer manufacturing method according to any one of (1) to (7).

The present invention is capable of providing a conductive layer manufacturing method that enables the manufacture of a conductive layer having excellent conductivity.

### BRIEF DESCRIPTION OF THE DRAWINGS

FIGS. 1A and 1B are cross-sectional views schematically showing a procedure for forming a copper oxide particle-containing precursor layer to be subjected to light irradiation treatment in the related art.

FIGS. 2A and 2B are cross-sectional views schematically showing a procedure for forming a precursor layer using a porous layer-carrying substrate.

FIGS. 3A to 3D are cross-sectional views schematically showing a procedure of a method for manufacturing a precursor layer-carrying support in another preferred embodiment.

### DETAILED DESCRIPTION OF THE INVENTION

A preferred embodiment of the conductive layer manufacturing method of the invention is described in detail below.

First, the features of the invention compared to the conventional art are described.

As described above, one feature of the invention is to control the filling ratio of copper oxide particles in a copper oxide particle-containing precursor layer. The present inventor has made an assumption on how the effect of the invention is attained as below. It should be noted that the scope of the invention is not limited by this assumption.

When copper oxide is reduced by irradiation with light, it is assumed that the most part of light used in irradiating a surface of a copper oxide-containing layer is absorbed, then the light having been absorbed at the layer surface is converted to heat, and the heat is transferred to the inside of the layer, thereby promoting the reduction of copper oxide. In the present invention, the filling ratio of copper oxide particles in the precursor layer is increased, that is, the distance between adjacent copper oxide particles is decreased. This probably leads to the enhancement of thermal conductivity and as a result the metallic copper content in the conductive layer is increased, whereby the conductivity of the conductive layer is improved. In addition, the conductivity of the conductive layer is improved probably because with the increase in the filling ratio of copper oxide particles, the amount of solvent remaining among the copper oxide particles is decreased and accordingly, a solvent to be vaporized due to rising temperature during irradiation with light is decreased, which suppresses the formation of voids in the conductive layer and therefore suppresses the occurrence of cracks in the conductive layer.

Detailed explanation will be made on a precursor layer-carrying support used in a reducing step in the conductive layer manufacturing method and then on a procedure of irradiation with light in the reducing step.

### [Precursor Layer-Carrying Support]

The precursor layer-carrying support used in this process includes a support and a copper oxide particle-containing precursor layer provided on the support. The filling ratio of copper oxide particles in the precursor layer is at least 65%.

Detailed explanation will be made on the support and then on the configuration of the precursor layer as well as a manufacturing procedure thereof.

### (Support)

The type of the support for use is not particularly limited as long as it supports the precursor layer. Exemplary materials of the support include resin, paper, glass, silicon-based semiconductors, compound semiconductors, metal oxides, metal nitrides, wood and composites thereof.

More specific examples thereof include resin bases composed of such materials as low density polyethylene resin, high density polyethylene resin, ABS resin, acrylic resin, styrene resin, vinyl chloride resin, polyester resin (polyethylene terephthalate), polyacetal resin, polysulphone resin, polyetherimide resin, polyether ketone resin and cellulose derivatives; paper bases composed of such materials as uncoated printing paper, ultralight weight coated printing paper, coated printing paper (art paper, coated paper), special printing paper, copy paper (PPC paper), unbleached wrapping paper (unglazed shipping sacks kraft paper, unglazed kraft paper), bleached wrapping paper (bleached kraft paper, machine glazed poster paper), coated board, chipboard and corrugated fiberboard; glass bases composed of such materials as soda-lime glass, borosilicate glass, silica glass and quartz glass; silicon-based semiconductor bases composed of such materials as amorphous silicon and polysilicon; compound semiconductor bases composed of such materials as CdS, CdTe and GaAs; metal bases composed of such materials as copper plate, iron plate and aluminum plate; inorganic bases composed of such materials as alumina, sapphire, zirconia, titania, yttrium oxide, indium oxide, indium tin oxide (ITO), indium zinc oxide (IZO), tin oxide (NESA), antimony-doped tin oxide (ATO), fluorine-doped tin oxide, zinc oxide, aluminum-doped zinc oxide (AZO), gallium-doped zinc oxide, aluminum nitride base material and silicon carbide; and composite bases composed of such as paper-resin composites exemplified by paper-phenolic resin, paper-epoxy resin and paper-polyester resin composites and glass-resin composites exemplified by glass cloth-epoxy resin, glass cloth-polyimide resin and glass cloth-fluororesin composites.

The support may have a laminated structure including two or more layers as described later.

### (Precursor Layer)

The precursor layer includes copper oxide particles and becomes a conductive layer when copper oxide is reduced to metallic copper by irradiation with light, which will be described later.

The filling ratio of copper oxide particles in the precursor layer is at least 65%. In particular, the filling ratio is preferably at least 70% and more preferably at least 75% because the conductive layer obtained has more excellent conductivity. The upper limit of the filling ratio is not particularly limited and is often up to 85% in terms of industrial productivity.

At a filling ratio of copper oxide particles in the precursor layer of less than 65%, the conductive layer obtained has poor conductivity.

A measurement method of the filling ratio of copper oxide particles in the precursor layer is as follows: A cross section of the precursor layer is observed in three or more places with a scanning electron microscope to acquire grayscale images having 256 gray levels. Of the 256 gray levels, the level of 100 is set to a threshold value to obtain a binary image in black and white, and white areas are taken as the copper oxide particles. The total area occupied by the copper oxide particles within the area of 1 μm long by 2 μm wide in each of the observed images is measured to calculate the filling ratio (%), and the arithmetic mean of the filling ratios calculated for the images in the three or more places is obtained as the filling ratio of the invention.

The thickness of the precursor layer is not particularly limited and is suitably selected depending on the intended use of the conductive layer to be formed. In particular, the thickness is preferably 0.5 to 10 μm and more preferably 1.0 to 5.0 μm because the copper oxide particles are more efficiently reduced by irradiation with light, which will be described later.

The precursor layer may be provided over the entire surface of the support or in a pattern form.

The precursor layer is densely filled with the copper oxide particles and therefore exhibits a low weight reduction rate in heat treatment. More specifically, when being heated at 300° C., the precursor layer has a weight reduction rate of preferably up to 30 wt % and more preferably up to 20 wt %. A low weight reduction rate means that a volatile ingredient such as a solvent is contained in the precursor layer in a small amount and accordingly, voids, cracks and the like are hardly generated in the conductive layer during irradiation with light which will be described later.

The weight reduction rate is measured by a method in which the precursor layer-carrying support is manufactured and subjected to drying treatment at 150° C. for 30 minutes, whereafter the precursor layer is peeled off from the support, and the peeled precursor layer undergoes TG-DTA measurement with an apparatus TG 8100 manufactured by Rigaku Corporation, in an air atmosphere, at a temperature rising rate of 10° C./min.

In the related art such as JP 2010-528428 A, a copper oxide particle-containing layer before being irradiated with light has a weight reduction rate about twice higher than that of the foregoing precursor layer, more specifically, a weight reduction rate of more than 30%, so that voids and the like are generated in the conductive layer during irradiation with light, resulting in poor conductivity.

The precursor layer contains the copper oxide particles preferably as the main ingredient. The “main ingredient” is used to mean that the copper oxide particles are contained in an amount of at least 80 wt %, preferably at least 85 wt % and more preferably at least 90 wt % with respect to the total weight of the precursor layer. The upper limit is not particularly limited and may be 100 wt %.

“Copper oxide” in the invention refers to a compound containing substantially no unoxidized copper and more specifically, a compound with which a peak derived from copper oxide is detected and at the same time, a peak derived from metal is not detected in X-ray crystallography. Containing substantially no copper means that the copper content is up to 1 wt % with respect to the copper oxide particles, although the copper content is not limited thereto.

Copper oxide is preferably copper(I) oxide or copper(II) oxide and more preferably copper(II) oxide because it is available at low cost and has low resistance.

The average particle size of the copper oxide particles is not particularly limited and is preferably up to 200 nm and more preferably up to 100 nm. The lower limit of the average particle size is also not particularly limited and preferably 10 nm or more.

An average particle size of 10 nm or more is preferable because the activity at particle surfaces remains at a moderate level and the handleability is excellent. An average particle size of up to 200 nm is preferable because this facilitates the formation of patterns such as interconnects by a printing method with the use of a copper oxide particle-containing solution as inkjet ink while the copper oxide particles are sufficiently reduced to metallic copper, resulting in excellent conductivity of the conductive layer to be obtained.

The average particle size refers to an average primary particle size. The average particle size is determined by measuring particle sizes (diameters) of at least 50 copper oxide particles through transmission electron microscopy (TEM) observation or scanning electron microscopy (SEM) observation and calculating the arithmetic mean of the measurements. When the shape of the copper oxide particles is not an exact circle in an image for use in the observation, the major axis is taken as the diameter in measurement.

Preferred examples of the copper oxide particles for use include CuO nanoparticles available from Kanto Chemical Co., Inc. and CuO nanoparticles available from Sigma-Aldrich.

The precursor layer may contain other ingredients than the copper oxide particles as long as the effect of the invention is not impaired. For instance, a polymer compound (polymer) may be contained as a binder ingredient. The polymer compound may be any of a natural polymer, a synthetic polymer and a mixture thereof. Preferred examples of the polymer compound include vinyl polymer (e.g., polyvinyl pyrrolidone), polyether, acrylic polymer, epoxy resin, urethane resin and rosin formulation. In addition, the precursor layer may contain a reducing group-bearing polymer that may be contained in a porous layer to be described later.

When the precursor layer contains other ingredients than the copper oxide particles, the other ingredients are contained in the precursor layer in an amount of preferably 0.1 to 20 wt %, more preferably 0.5 to 15 wt % and even more preferably 1 to 13 wt %.

### (Precursor Layer Manufacturing Method)

A method for manufacturing the precursor layer-carrying support is not particularly limited as long as the filling ratio of copper oxide particles in the precursor layer falls within the predetermined range.

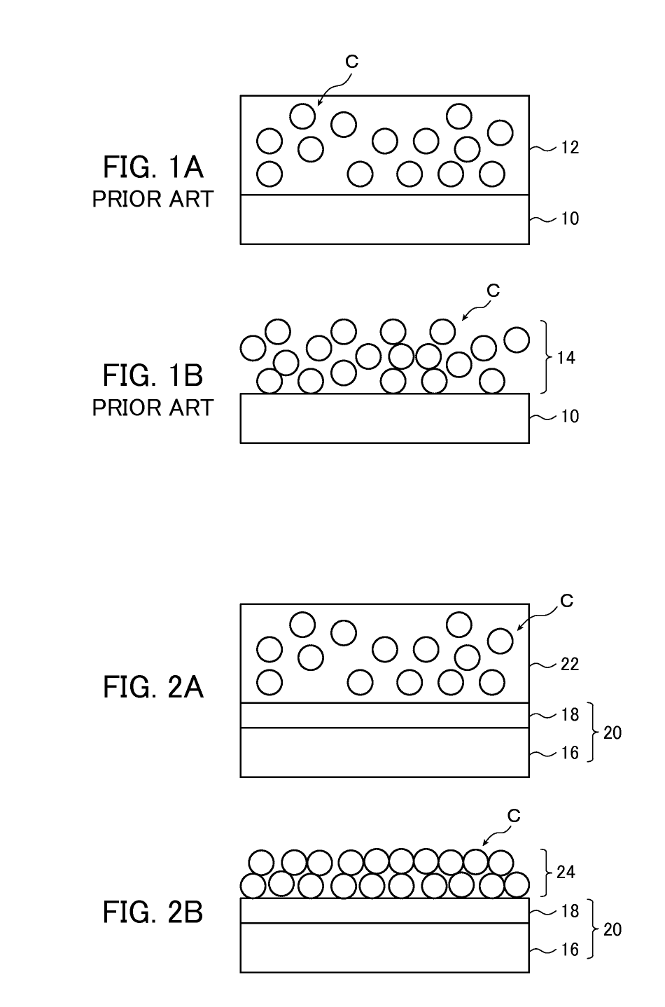

One preferred embodiment of the method for manufacturing the precursor layer-carrying support is for instance a method in which a copper oxide particle-containing solution is applied onto a porous layer-carrying substrate including a substrate and a porous layer provided on the substrate to thereby form the precursor layer. This embodiment is described with reference to FIGS. 1 and 2.

In the related art described in JP 2010-528428 A, when a copper oxide particle-containing precursor layer to be subjected to irradiation with light is formed, a solution containing copper oxide particles C is applied onto a support 10 to form a coating 12 as shown in FIG. 1A and then a solvent is removed to form a layer 14 containing the copper oxide particles C (FIG. 1B). In this method, when the solvent is removed, voids are easily generated in the layer and therefore space among the copper oxide particles C is increased, so that the filling ratio of the copper oxide particles C in the layer 14 is lowered. When the thus configured layer 14 is irradiated with light as described later, heat caused by light absorption at the surface of the layer 14 is not efficiently transferred to the inside of the layer 14 due to the low filling ratio of the copper oxide particles C and as a result, the copper oxide particles C remain inside the layer 14 without being reduced and sintered, resulting in poor conductivity.

Meanwhile, in the case of using a porous layer-carrying substrate 20 including a substrate 16 and a porous layer 18 provided on the substrate 16 as shown in FIG. 2A, the solution containing the copper oxide particles C is applied onto the porous layer-carrying substrate 20 to form a coating 22 in the same manner as the related art. At this time, the porous layer 18 under the coating 22 absorbs a solvent in the coating 22 so that the amount of solvent in the coating 22 is decreased. In other words, the porous layer 18 serves as a driving force for absorbing the solvent like a filter (filter paper). Consequently, a precursor layer 24 densely packed or filled with the copper oxide particles C is formed. When the thus configured precursor layer 24 is irradiated with light, heat generated at the surface of the precursor layer 24 is efficiently transferred to the inside of the precursor layer 24 so that the copper oxide particles C present inside the precursor layer 24 are also reduced to metallic copper, whereby a conductive layer having excellent conductivity is obtained as described above.

When the solution containing the copper oxide particles C is applied onto the support 10 as shown in FIG. 1A and the porous layer-carrying substrate 20 as shown in FIG. 2A under the same conditions, the precursor layer 24 shown in FIG. 2B is generally smaller in thickness than the layer 14 containing the copper oxide particles C shown in FIG. 1B. This is because the copper oxide particles C are filled more densely in the precursor layer 24 than in the layer 14 containing the copper oxide particles C as shown in FIGS. 1B and 2B. Note that when the solution containing the copper oxide particles C are applied onto the support 10 and the porous layer-carrying substrate 20 under the same conditions as described above, the precursor layer 24 often has a thickness of up to about 60% of the thickness of the layer 14 containing the copper oxide particles C.

The type of the substrate in the porous layer-carrying substrate is not particularly limited as long as it can support the porous layer and may be a substrate composed of the materials illustrated for the above-described support. In particular, the substrate is preferably a thermoplastic film. The thermoplastic film is preferably a film selected from the group consisting of, for instance, polyimide films, polyethylene terephthalate films, polyethylene naphthalate films, polyamide films, polyurethane films, polycarbonate films, polystyrene films, polytetrafluoroethylene films, polybutadiene films, polyolefin films, poly-4-methylpentene films, ionomer films, ABS resin films, polysulfone films, cellulose triacetate films, ethyl cellulose films, butyl cellulose acetate films, polydimethylsiloxane films, polyester films, ethylene-vinyl acetate copolymer films, polyolefin fluoride films, polychloroprene films and butyl rubber films.

The porous layer is not limited as long as it has a great number of pores therein and exemplary porous layers include a layer having a porous structure of three-dimensional network type such as microporous membrane type and nonwoven fabric type. The microporous membrane type layer refers to a layer having therein a great number of micropores which are connected to each other whereby gas or liquid can pass through the layer from one surface to the opposite surface.

The porous layer thickness is not particularly limited and is preferably 0.5 to 500 μm and more preferably 1.0 to 100 μm because the conductive layer obtained has more excellent conductivity.

The average pore size of pores in the porous layer is not particularly limited and is preferably smaller than the average particle size of the copper oxide particles because the conductive layer obtained has more excellent conductivity. This embodiment can suppress the penetration of the copper oxide particles into the porous layer and therefore makes it possible to obtain on the porous layer the precursor layer that is more densely filled or packed with the copper oxide particles.

The average pore size of pores in the porous layer is preferably 1 to 100 nm, more preferably 1 to 50 nm and even more preferably 5 to 20 nm. At an average pore size within the foregoing range, the conductive layer obtained has more excellent conductivity.

The average pore size of pores in the porous layer is determined using, for example, mercury intrusion porosimetry, more specifically by obtaining measurement data of pore size measured by mercury intrusion porosimetry and defining the pore size at the peak position in the measurement data as the average pore size in the porous layer.

The porosity of the porous layer is not particularly limited and is preferably 30 to 90% and more preferably 50 to 80% because the conductive layer obtained has more excellent conductivity.

The porosity of the porous layer is measured by oil impregnation method. More specifically, the porous layer is caused to absorb a high boiling point solvent such as diethylene glycol; the weight increase of the porous layer due to absorption is determined after excess solvent having not been absorbed by the porous layer is removed; and the absorption volume (i.e., void volume) is obtained from the density of the solvent.

The thermal conductivity of a material making up the porous layer is not particularly limited and is preferably up to 20 (W/mK) and more preferably up to 10 (W/mK) because the conductive layer obtained has more excellent conductivity. When the porous layer has low thermal conductivity, the copper oxide particles positioned even in the lower part in the precursor layer are also easily reduced. More specifically, exemplary materials making up the porous layer include metal oxides (particularly, oxides containing one selected from the group consisting of the elements of Groups 5A, 3B and 4B of the periodic table) such as silica (silicon oxide), titania (titanium oxide), zirconia (zirconium oxide) and alumina (aluminum oxide). Of these, silica and zirconia are preferred because the conductive layer obtained has more excellent conductivity.

The thermal conductivity of the porous layer is preferably lower than that of the precursor layer. This embodiment enables the conductivity of the conductive layer to be improved.

In the present invention, the thermal conductivity of the porous layer and the precursor layer is calculated by a Maxwell equation below, and the apparent thermal conductivity λe expressed by Equation (1) is employed as the thermal conductivity.

### [Equation 1]

$${λ}_{e} = {λ}_{s} \times \frac{2 {λ}_{s} + {λ}_{g} - 2 φ ( {λ}_{s} - {λ}_{g} )}{2 {λ}_{s} + {λ}_{g} + φ ( {λ}_{s} - {λ}_{g} )} \qquad Equation ( 1 )$$

In Equation (1), λs denotes the thermal conductivity of a material making up the porous layer or the precursor layer, λg the thermal conductivity (0.02) of air, and φ the porosity of the porous layer or the precursor layer. For example, the thermal conductivity of the copper oxide particles is 3, that of silica is 1.4 and that of zirconia is 2.0.

The porous layer may contain an organic polymer, and a reducing group-bearing polymer may be contained because the conductive layer obtained has more excellent conductivity. When the porous layer contains this type of polymer, the reduction of copper oxide is further promoted so that the conductive layer obtained has more excellent conductivity.

The reducing group refers to a group contributing to the reduction of copper oxide and exemplified by hydroxyl and amino groups. Specific examples of the reducing group-bearing organic polymer include polyvinyl alcohol.

The method for manufacturing the porous layer on the substrate is not particularly limited and exemplary methods include a method in which a composition containing particles of materials such as silica and zirconia (particularly, metal oxides) as described above as well as a solvent is applied onto the substrate, whereafter the solvent is removed, thereby forming the porous layer on the substrate. Another method is laminating on the substrate the porous layer separately prepared.

The foregoing method of applying the copper oxide particle-containing solution onto the porous layer-carrying substrate is not particularly limited and any known method may be used. Exemplary methods include coating methods such as screen printing, dip coating, spray coating, spin coating and inkjet coating.

The coating is not particularly limited in shape and may cover the entire porous layer surface or may be in a pattern form such as interconnect and dot forms.

After the solution is applied onto the porous layer-carrying substrate, the substrate may be subjected to drying treatment to remove the solvent, if necessary. The remaining solvent is preferably removed because the generation of fine cracks and voids, which is caused by the expansion of the solvent at vaporization, can be suppressed, resulting in excellent conductivity of the conductive layer and good adhesion between the conductive layer and the porous layer-carrying substrate.

Drying treatment may be performed with a hot air dryer and the drying temperature is preferably such a temperature that the reduction of the copper oxide particles does not occur. Heat treatment is performed preferably at 40 to 200° C., more preferably at 50° C. or more but less than 150° C., and even more preferably at 70 to 120° C.

The type of the solvent contained in the copper oxide particle-containing solution is not particularly limited, and water and organic solvents such as alcohols, ethers and esters may be used. Of these, use is preferably made of water, hydroxyl group-bearing, mono- to trihydric aliphatic alcohols, alkyl ethers derived from the aliphatic alcohols, alkyl esters derived from the aliphatic alcohols, and mixtures thereof because of more excellent compatibility with the copper oxide particles.

When water is used as the solvent, the water preferably has a purity at the ion exchanged water level.

Examples of the hydroxyl group-bearing, mono- to trihydric aliphatic alcohols include methanol, ethanol, 1-propanol, 1-butanol, 1-pentanol, 1-hexanol, cyclohexanol, 1-heptanol, 1-octanol, 1-nonanol, 1-decanol, glycidol, methylcyclohexanol, 2-methyl-1-butanol, 3-methyl-2-butanol, 4-methyl-2-pentanol, isopropyl alcohol, 2-ethylbutanol, 2-ethylhexanol, 2-octanol, terpineol, dihydroterpineol, 2-methoxyethanol, 2-ethoxyethanol, 2-n-butoxyethanol, carbitol, ethyl carbitol, n-butyl carbitol, diacetone alcohol, ethylene glycol, diethylene glycol, triethylene glycol, tetraethylene glycol, propylene glycol, trimethylene glycol, dipropylene glycol, tripropylene glycol, 1,2-butylene glycol, 1,3-butylene glycol, 1,4-butylene glycol, pentamethylene glycol, hexylene glycol and glycerin.

In particular, hydroxyl group-bearing, mono- to trihydric aliphatic alcohols having 1 to 6 carbon atoms are preferred because they each have a moderate boiling point and therefore hardly remain after the conductive layer is formed as well as having good compatibility with the aforementioned vinyl polymer and copper oxide particles, and more preferred are methanol, ethylene glycol, glycerin, 2-methoxyethanol, diethylene glycol and isopropyl alcohol.

Exemplary ethers include the foregoing alkyl ethers derived from the alcohols, such as diethyl ether, diisobutyl ether, dibutyl ether, methyl-t-butyl ether, methyl cyclohexyl ether, diethyleneglycol dimethyl ether, diethyleneglycol diethyl ether, triethyleneglycol dimethyl ether, triethyleneglycol diethyl ether, tetrahydrofuran, tetrahydropyran and 1,4-dioxane. In particular, alkyl ethers having 2 to 8 carbon atoms derived from hydroxyl group-bearing, mono- to trihydric aliphatic alcohols having 1 to 4 carbon atoms are preferred, and diethyl ether, diethyleneglycol dimethyl ether and tetrahydrofuran are more preferred.

Exemplary esters include the foregoing alkyl esters derived from the alcohols, such as methyl formate, ethyl formate, butyl formate, methyl acetate, ethyl acetate, butyl acetate, methyl propionate, ethyl propionate, butyl propionate and γ-butyrolactone. In particular, alkyl esters having 2 to 8 carbon atoms derived from hydroxyl group-bearing, mono- to trihydric aliphatic alcohols having 1 to 4 carbon atoms are preferred, and methyl formate, ethyl formate and methyl acetate are more preferred.

Of the foregoing solvents, water is particularly preferred for use as the main solvent because of its moderate boiling point. The main solvent refers to a solvent of which the content is highest among the solvents contained.

The aforementioned solution may contain other ingredients than the copper oxide particles and the solvent.

For instance, the solution may contain a surfactant. The surfactant serves to improve the dispersibility of the copper oxide particles. The type of the surfactant is not particularly limited and exemplary surfactants include anionic surfactants, cationic surfactants, nonionic surfactants, fluorosurfactants and amphoteric surfactants. These surfactants may be used alone or in combination of two or more.

In addition, a polymer compound (polymer) may be contained as a binder ingredient. The type of the polymer compound is defined as with the type of the polymer compound contained in the precursor layer.

The copper oxide particle content in the solution is not particularly limited and is preferably 5 to 60 wt % and more preferably 10 to 50 wt % with respect to the total weight of the solution because a sufficiently thick conductive layer having more excellent conductivity can be obtained while the viscosity of the solution is prevented from increasing so that the solution is usable as inkjet ink.

The solvent content in the solution is not particularly limited and is preferably 5 to 90 wt % and more preferably 15 to 80 wt % with respect to the total weight of the solution because the viscosity of the solution is prevented from increasing and the handleability is more excellent. The solution preferably contains water as the solvent and the water content is preferably 50 wt % or more with respect to the total weight of the solution.

The solution preferably has a viscosity adjusted to be suitable for use in printing such as inkjet printing and screen printing. The viscosity is preferably 1 to 50 cP and more preferably 5 to 20 cP when the solution is to be discharged in inkjet printing, and preferably 1,000 to 100,000 cP and more preferably 10,000 to 80,000 cP in screen printing.

A method for preparing the solution is not particularly limited and any known method may be used. For example, the solution may be prepared by adding the copper oxide particles to the solvent and then dispersing the ingredients in the solvent by known methods such as an ultrasonic method (e.g., a treatment using an ultrasonic homogenizer), a mixer method, a three-roll method, a ball mill method and the like.

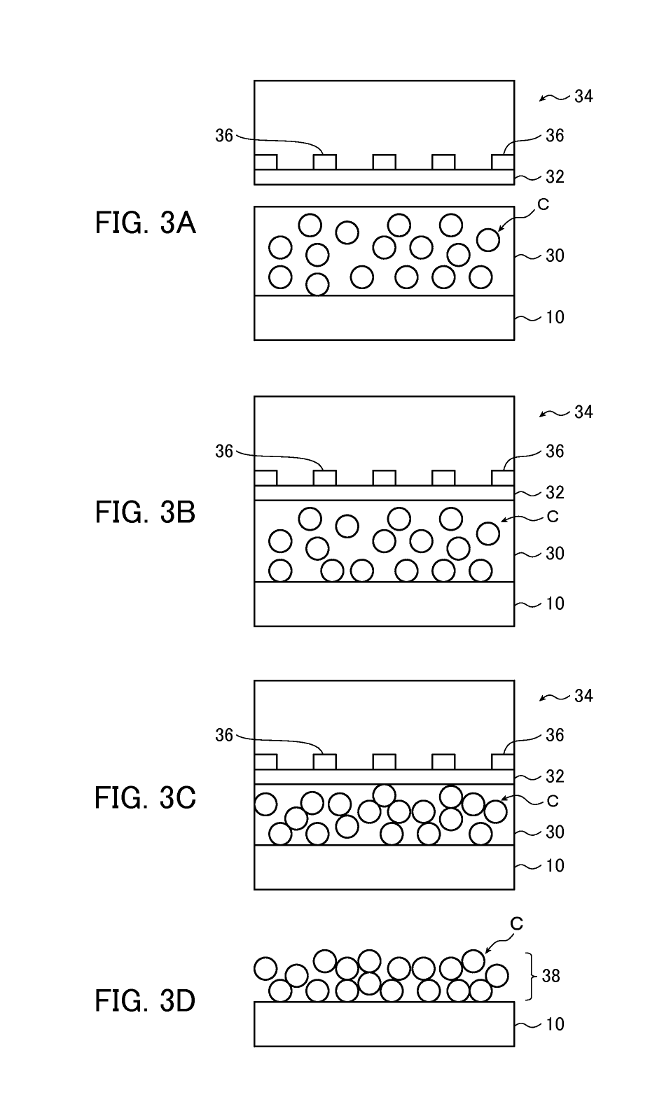

Another preferred embodiment of the precursor layer-carrying support manufacturing method is a method in which the copper oxide particle-containing solution is applied onto the support to form the coating containing the copper oxide particles and the solvent; and then a film having through-holes is pressed against the coating to remove the solvent in the coating through the through-holes, thereby forming a precursor layer. This embodiment is described with reference to FIG. 3.

First, a solution containing the copper oxide particles C is applied onto the support 10 to form a coating 30 as shown in FIG. 3A. Thereafter, as shown in FIG. 3B, a filter member 34 provided on its surface with a film 32 having through-holes is prepared, and the filter member 34 is pressed against the coating 30 so that the film 32 having through-holes is brought into contact with a surface of the coating 30. The filter member 34 further includes film holding members 36 that hold the film 32 having through-holes. By removing the solvent in the coating 30 under reduced pressure via the through-holes of the film 32 with the filter member 34 being pressed against the coating 30, the filling ratio of the copper oxide particles C in the coating 30 is enhanced (FIG. 3C). A precursor layer 38 as described above is formed by further pressing the filter member 34 and removing the solvent under reduced pressure (FIG. 3D).

The film having through-holes is not particularly limited as long as it has through-holes allowing the solvent to pass therethrough and exemplary films include a film having a porous structure of three-dimensional network type such as microporous membrane type and nonwoven fabric type. The through-holes refer to holes through which gas or liquid can pass from one surface of the film to the opposite surface thereof. One specific example of the film having through-holes is an Isopore membrane filter manufactured by Merck Millipore.

The average pore size of the through-holes is not particularly limited and is preferably up to 100 nm because the filling ratio of copper oxide particles in the precursor layer is more enhanced.

While drying under reduced pressure is performed to remove the solvent in the process shown in FIGS. 3A to 3D, drying may be performed at normal temperature and under normal pressure without reducing pressure depending on the type of the solvent.

(Procedure of Irradiation with Light)

In the reducing step, light irradiation treatment is performed on the precursor layer of the precursor layer-carrying support described above. In the light irradiation treatment, a portion provided with the precursor layer is irradiated with light for a short time. This treatment enables copper oxide to be reduced and sintered, enables the support to avoid deterioration caused by prolonged heating and allows the conductive layer and the support to have more excellent adhesion. More specifically, in response to the light irradiation treatment, the copper oxide particles absorb light and accordingly, the reduction of copper oxide is promoted, while the absorbed light is converted to heat and the heat is transferred to the inside of the precursor layer so that the copper oxide inside the precursor layer are reduced and sintered, thereby obtaining metallic copper. With this treatment, metallic copper particles resulting from the reduction of the copper oxide particles fuse together to thereby form grains, and the grains adhere and fuse to each other to thereby form the conductive layer. In other words, light sintering is performed.

The light source for use in light irradiation treatment is not particularly limited and exemplary light sources include mercury lamp, metal halide lamp, xenon lamp, chemical lamp and carbon arc lamp. Examples of the radiation include electron rays, X-rays, ion beams and far infrared rays, and g-line rays, i-line rays, deep UV rays and high-density energy beams (laser beams) may also be used.

Preferred specific examples include scanning exposure with an infrared laser, high-intensity flash exposure with a xenon discharge lamp and exposure with an infrared lamp.

The light irradiation is performed preferably with a flash lamp, and pulsed light irradiation using a flash lamp is more preferred. The irradiation with high-energy pulsed light is capable of intensively heating a surface of the precursor layer in an extremely short time and therefore, the heat affects the support to a minor extent.

The pulsed light has an irradiation energy of preferably 1 to 100 J/cm² and more preferably 1 to 30 J/cm² and a pulse width of preferably 1 μs to 100 ms and more preferably 10 μs to 10 ms. The irradiation time of the pulsed light is preferably 1 to 100 ms, more preferably 1 to 50 ms and even more preferably 1 to 20 ms.

During or after light irradiation treatment, heating treatment may optionally be performed. In particular, the heating temperature is preferably 100 to 300° C. and more preferably 150 to 250° C. and the heating time is preferably 5 to 120 minutes and more preferably 10 to 60 minutes because the conductive layer with more excellent conductivity can be formed in a short time.

The atmosphere for light irradiation treatment is not particularly limited, and examples thereof include air atmosphere, inert atmosphere and reducing atmosphere. The inert atmosphere refers to an atmosphere filled with inert gases such as argon, helium, neon and nitrogen, and the reducing atmosphere refers to an atmosphere in which a reducing gas such as hydrogen or carbon monoxide is present.

### (Conductive Layer)

A metallic copper-containing conductive layer (metallic copper layer) is obtained through the foregoing steps.

The thickness of the conductive layer is not particularly limited and is appropriately adjusted depending on the intended use. When used particularly for a printed circuit board, the conductive layer preferably has a thickness of 0.01 to 1000 μm and more preferably 0.1 to 100 μm.

The layer thickness is a value (average) obtained by measuring the thickness of the conductive layer in any three or more places and calculating the arithmetic mean of the measurements.

The conductive layer has a volume resistivity of preferably less than 1×10⁻³ Ωcm, more preferably less than 1×10⁻⁴ Ωcm and even more preferably less than 0.5×10⁻⁵ Ωcm in terms of conductive properties.

The volume resistivity can be calculated by measuring the surface resistivity of the conductive layer by four point probe method and then multiplying the obtained surface resistivity by the layer thickness.

The conductive layer may be provided over the entire surface of the support or in a pattern form. The patterned conductive layer is useful as conductive interconnects (interconnects) of a printed circuit board or the like.

Exemplary methods for forming the patterned conductive layer includes a method in which the precursor layer is placed on the support in a pattern form, followed by irradiation with light; and a method in which a conductive layer provided over the entire surface of the support is etched in a pattern form.

The etching method is not particularly limited and for example, a known subtractive or semi-additive method may be employed.

In cases where the patterned conductive layer is configured as a multilayer circuit board, an insulating layer (insulating resin layer, interlayer dielectric film, solder resist) may be further formed on the surface of the patterned conductive layer and further interconnects (metal pattern) may be formed on the surface thereof.

The material of the insulating layer is not particularly limited and examples thereof include epoxy resin, aramid resin, crystalline polyolefin resin, amorphous polyolefin resin, fluorine-containing resins (e.g., polytetrafluoroethylene, perfluorinated polyimide and perfluorinated amorphous resin), polyimide resin, polyethersulfone resin, polyphenylene sulfide resin, polyether ether ketone resin and liquid-crystal resin.

Of these, the insulating layer contains preferably epoxy resin, polyimide resin or liquid-crystal resin and more preferably epoxy resin in terms of adhesion, dimension stability, heat resistance and electrical insulating properties. One specific example is ABF-GX13 manufactured by Ajinomoto Fine-Techno Co., Inc.

The solder resist that may be employed as a material of the insulating layer used for protecting interconnects is described in, for example, JP 10-204150 A and JP 2003-222993 A in detail, and the materials of the solder resist stated therein are applicable to the present invention as desired. Commercial products such as PFR800 and PSR4000 (trade names) manufactured by Taiyo Ink Mfg. Co., Ltd. and SR7200G manufactured by Hitachi Chemical Company, Ltd. may be used for the solder resist.

The support having the thus formed conductive layer (conductive layer-carrying support) is adaptable for various purposes and, for instance, may be used for a printed circuit board, a TFT, an FPC and an RFID.

### EXAMPLES

The invention is described below in further detail by way of examples. However, the invention should not be construed as being limited to the following examples.

Copper oxide ink (ICI-003; copper oxide particle average particle size: 88 nm) manufactured by NovaCentrix (hereinafter also called “copper oxide particle-containing solution X”) and an aqueous dispersion obtained by dispersing in water CuO particles (average particle size: 61 nm) manufactured by Kanto Chemical Co., Inc. with no use of a dispersant or the like (hereinafter also called “copper oxide particle-containing solution Y”) were used as copper oxide particle-containing solutions to be described later. Copper ink (CI) manufactured by Intrinsiq Materials Inc. was used as a solution containing metallic copper particles (hereinafter also called “metallic copper particle-containing solution”).

### Synthesis Example 1

### Manufacture of Porous Layer-Carrying Substrate 1

A composition for porous layer formation was prepared by adding 50 g of silica particles (TECNAPOW-SIO2, manufactured by TECNAN) and 10 g of polyvinyl alcohol into water (100 g). Thereafter, the composition for porous layer formation was applied onto a substrate (PET) and the substrate was heated at 60° C. for 60 minutes to thereby manufacture a porous layer-carrying substrate 1. The porous layer thickness was 40 μm.

The average pore sizes and the porosities of porous layers obtained are all shown in Table 1. The average pore size of pores in the porous layer was determined using mercury intrusion porosimetry, more specifically by obtaining measurement data of pore size measured by mercury intrusion porosimetry and defining the pore size at the peak position in the measurement data as the average pore size in the porous layer. The porosity was determined as follows: The porous layer obtained was caused to absorb diethylene glycol, the weight increase of the porous layer due to absorption was determined after excess solvent having not been absorbed was removed, the absorption volume (i.e., void volume) was obtained from the density of the solvent, and the porosity (%) (void volume/porous layer total volume×100) was calculated.

### Synthesis Example 2

### Manufacture of Porous Layer-Carrying Substrate 2

A porous layer-carrying substrate 2 was manufactured according to the same procedure as in Synthesis Example 1 except that zirconia particles (TECNAPOW-ZRO2, manufactured by TECNAN) were used in place of the silica particles.

### Synthesis Example 3

### Manufacture of Porous Layer-Carrying Substrate 3

A porous layer-carrying substrate 3 was manufactured according to the same procedure as in Synthesis Example 1 except that the amount of the polyvinyl alcohol in Synthesis Example 1 was changed to 5 g.

### Synthesis Example 4

### Manufacture of Porous Layer-Carrying Substrate 4

A porous layer-carrying substrate 4 was manufactured according to the same procedure as in Synthesis Example 1 except that the amount of the silica particles in Synthesis Example 1 was changed to 80 g.

### Synthesis Example 5

### Manufacture of Porous Layer-Carrying Substrate 5

A porous layer-carrying substrate 5 was manufactured according to the same procedure as in Synthesis Example 1 except that titania particles (TECNAPOW-TIO2, manufactured by TECNAN) were used in place of the silica particles and that the amount of the polyvinyl alcohol was changed to 5 g.

### Synthesis Example 6

### Manufacture of Porous Layer-Carrying Substrate 6

A porous layer-carrying substrate 6 was manufactured according to the same procedure as in Synthesis Example 1 except that titania particles (TECNAPOW-TIO2, manufactured by TECNAN) were used in place of the silica particles.

### Synthesis Example 7

### Manufacture of Porous Layer-Carrying Substrate 7

A porous layer-carrying substrate 7 was manufactured according to the same procedure as in Synthesis Example 1 except that alumina particles (TECNAPOW-AL203, manufactured by TECNAN) were used in place of the silica particles.

### Example 1

The copper oxide particle-containing solution X was applied onto the porous layer-carrying substrate 1 (10×10 mm) with an inkjet printer (DMP-2800, manufactured by FUJIFILM Dimatix, Inc.) to thereby form a coating, and then the porous layer-carrying substrate 1 having the coating thereon was placed on a hot plate and dried at 100° C. for 10 minutes to remove a solvent, thereby manufacturing a precursor layer-carrying support 1. The filling ratio of copper oxide particles in the resultant precursor layer was 76%. The precursor layer thickness was 2.0 μm.

The filling ratio of copper oxide particles in the precursor layer was determined as follows: A cross section of the precursor layer was observed in three places with a scanning electron microscope, the total area occupied by the copper oxide particles within the area of 1 μm long by 2 μm wide in each of the observed images was measured by the method described above to calculate the filling ratio (%), and the arithmetic mean of the filling ratios as calculated for the images in the three places was obtained.

Subsequently, the precursor layer of the precursor layer-carrying support 1 was irradiated with light at an irradiation energy of 5 J/cm² with a photonic sintering system Sinteron 2000, manufactured by Xenon Corporation, to thereby obtain a conductive layer.

Thereafter, the thickness of the resultant conductive layer was measured with a stylus-type step profiler Dektak 3. The layer thickness was determined by measuring the layer thickness of the conductive layer in certain three places and calculating the arithmetic mean of the measurements. Furthermore, the volume resistivity was measured by the four point probe method with a four point probe-type resistivity meter (low resistivity meter Loresta, manufactured by Mitsubishi Chemical Analytech Co., Ltd.) on the basis of the conductive layer thickness obtained. The evaluation result is shown in Table 1.

The volume resistivity obtained was evaluated according to the following evaluation criteria. It is necessary for each sample to be rated “AA,” “A” or “B” for practical use.

AA: less than 0.5×10⁻⁵ Ωcm
A: 0.5×10⁻⁵ Ωcm or more but less than 0.1×10⁻⁴ Ωcm
B: 0.1×10⁻⁴ Ωcm or more but less than 0.1×10⁻³ Ωcm
C: 0.1×10⁻³ Ωcm or more but less than 0.1×10⁻² Ωcm
D: 0.1×10⁻² Ωcm or more

### Example 2

A conductive layer was obtained according to the same procedure as in Example 1 except that the porous layer-carrying substrate 2 was used in place of the porous layer-carrying substrate 1. The evaluation result is shown in Table 1.

### Example 3

A conductive layer was obtained according to the same procedure as in Example 1 except that the porous layer-carrying substrate 3 was used in place of the porous layer-carrying substrate 1. The evaluation result is shown in Table 1.

### Example 4

A conductive layer was obtained according to the same procedure as in Example 1 except that the porous layer-carrying substrate 4 was used in place of the porous layer-carrying substrate 1. The evaluation result is shown in Table 1.

### Example 5

A conductive layer was obtained according to the same procedure as in Example 1 except that the porous layer-carrying substrate 5 was used in place of the porous layer-carrying substrate 1. The evaluation result is shown in Table 1.

### Example 6

A conductive layer was obtained according to the same procedure as in Example 1 except that the porous layer-carrying substrate 6 was used in place of the porous layer-carrying substrate 1 and that the irradiation energy was changed from 5 J/cm² to 10 J/cm². The evaluation result is shown in Table 1.

### Example 7

A conductive layer was obtained according to the same procedure as in Example 1 except that the porous layer-carrying substrate 7 was used in place of the porous layer-carrying substrate 1 and that the irradiation energy was changed from 5 J/cm² to 10 J/cm². The evaluation result is shown in Table 1.

### Example 8

A conductive layer was obtained according to the same procedure as in Example 3 except that the copper oxide particle-containing solution Y was used in place of the copper oxide particle-containing solution X. The evaluation result is shown in Table 1.

### Example 9

A conductive layer was obtained according to the same procedure as in Example 4 except that the copper oxide particle-containing solution Y was used in place of the copper oxide particle-containing solution X. The evaluation result is shown in Table 1.

### Comparative Example 1

A conductive layer was obtained according to the same procedure as in Example 1 except that a substrate (PET) was used in place of the porous layer-carrying substrate 1. The evaluation result is shown in Table 1.

No porous layer was used in Comparative Example 1.

### Comparative Example 2

A conductive layer was obtained according to the same procedure as in Comparative Example 1 except that the metallic copper particle-containing solution was used in place of the copper oxide particle-containing solution X. The evaluation result is shown in Table 1.

Neither porous layer nor copper oxide particles were used in Comparative Example 2.

### Comparative Example 3

A conductive layer was obtained according to the same procedure as in Example 1 except that the metallic copper particle-containing solution was used in place of the copper oxide particle-containing solution X. The evaluation result is shown in Table 1.

No copper oxide particles were used in Comparative Example 3.

### Comparative Example 4

Although the manufacture of a conductive layer was tried according to the same procedure as in Example 1 except that the metallic copper particle-containing solution was used in place of the copper oxide particle-containing solution X and that the irradiation energy was changed from 5 J/cm² to 5.5 J/cm², the portion to be a conductive layer was scattered during irradiation with light and the manufacture of a conductive layer was failed.

No copper oxide particles were used in Comparative Example 4.

In the “Type” fields of “Used solution” column in Table 1, “X” denotes the copper oxide particle-containing solution X, “Y” the copper oxide particle-containing solution Y and “CI” the metallic copper particle-containing solution.

Values in the “Apparent thermal conductivity” fields of “Porous layer” and “Precursor layer” columns were calculated by Equation (1) for the apparent thermal conductivity λe as described above. [Table 1]

TABLE 1

| | | | Porous layer | | | | Precursor layer | | | |
|---|---|---|---|---|---|---|---|---|---|---|
| | | | | | | Apparent | | Apparent | | |
| | Used solution | | | Average | | thermal | Filling | thermal | Light | |
| | | Particle | | pore size | Porosity | conductivity | ratio | conductivity | energy | |
| | Type | type | Material | (nm) | (%) | (W/mk) | (%) | (W/mk) | (J/cm²) | Conductivity |
| EX 1 | X | CuO | Silica | 20 | 65 | 0.39 | 76 | 2.08 | 5 | AA |
| EX 2 | X | CuO | Zirconia | 20 | 65 | 0.54 | 75 | 2.04 | 5 | AA |
| EX 3 | X | CuO | Silica | 50 | 80 | 0.22 | 75 | 1.94 | 5 | A |
| EX 4 | X | CuO | Silica | 5 | 40 | 0.71 | 75 | 2.04 | 5 | A |
| EX 5 | X | CuO | Titania | 30 | 75 | 1.55 | 75 | 2.04 | 5 | A |
| EX 6 | X | CuO | Titania | 20 | 65 | 2.24 | 76 | 2.08 | 10 | B |
| EX 7 | X | CuO | Alumina | 20 | 65 | 7.94 | 75 | 2.04 | 10 | B |
| EX 8 | Y | CuO | Silica | 50 | 80 | 0.22 | 83 | 2.33 | 5 | A |
| EX 9 | Y | CuO | Silica | 5 | 40 | 0.71 | 82 | 2.15 | 5 | A |
| CE 1 | X | CuO | — | — | — | — | 56 | 1.11 | 5 | C |
| CE 2 | CI | Cu | — | — | — | — | 62 | 208 | 5 | D |
| CE 3 | CI | Cu | Silica | 20 | 65 | 0.39 | 77 | 276 | 5 | C |
| CE 4 | CI | Cu | Silica | 20 | 65 | 0.39 | 77 | 276 | 5.5 | — |

It was confirmed from the results shown in Table 1 that each conductive layer obtained by irradiating with light the precursor layer having a copper oxide particle filling ratio of at least 65% exhibits excellent conductivity.

In particular, it was confirmed from the comparison of Examples 1, 2, 6 and 7 that each conductive layer with the porous layer made of silica or zirconia exhibits more excellent conductivity.

It was confirmed from the comparison of Examples 1, 3 and 4 that the conductive layer with the porous layer having an average pore size of 5 to 20 nm and a porosity of 50 to 80% exhibits more excellent conductivity.

Furthermore, it was confirmed from the comparison of Examples 1 to 7 that each conductive layer exhibits more excellent conductivity when the precursor layer has a thermal conductivity higher than that of the porous layer.

In contrast, in Comparative Examples 1 to 3 in which the requirements of the conductive layer manufacturing method of the invention were not satisfied, the resultant conductive layers exhibit poor conductivity.

For example, in Comparative Example 1 in which the copper oxide particle filling ratio was less than the predetermined value and Comparative Examples 2 and 3 in which no copper oxide particles were used, the resultant conductive layers exhibit poorer conductivity as compared to Examples.

In Comparative Example 4, the layer manufacture was failed.

What is claimed is:

1. A conductive layer manufacturing method comprising a reducing step of irradiating with light a precursor layer-carrying support having a support and a copper oxide particle-containing precursor layer provided on the support so as to reduce copper oxide particles contained in the precursor layer to thereby form a metallic copper-containing conductive layer,
wherein a filling ratio of the copper oxide particles in the precursor layer is at least 65%.

2. The conductive layer manufacturing method according to claim 1,
wherein the support is a porous layer-carrying substrate having a substrate and a porous layer provided on the substrate, and
wherein the reducing step is preceded by a precursor layer forming step of forming the precursor layer by applying a copper oxide particle-containing solution onto the porous layer-carrying substrate.

3. The conductive layer manufacturing method according to claim 2, wherein the porous layer has an average pore size smaller than an average particle size of the copper oxide particles.

4. The conductive layer manufacturing method according to claim 2, wherein materials making up the porous layer include at least one selected from the group consisting of silica and zirconia.

5. The conductive layer manufacturing method according to claim 2, wherein the porous layer has a porosity of 50 to 80%.

6. The conductive layer manufacturing method according to claim 2, wherein the porous layer has an average pore size of 5 to 20 nm.

7. The conductive layer manufacturing method according to claim 2, wherein the porous layer has a thermal conductivity lower than that of the precursor layer.

8. A printed circuit board having a conductive layer manufactured by the conductive layer manufacturing method according to claim 1.

9. The conductive layer manufacturing method according to claim 3, wherein materials making up the porous layer include at least one selected from the group consisting of silica and zirconia.

10. The conductive layer manufacturing method according to claim 3, wherein the porous layer has a porosity of 50 to 80%.

11. The conductive layer manufacturing method according to claim 4, wherein the porous layer has a porosity of 50 to 80%.

12. The conductive layer manufacturing method according to claim 3, wherein the porous layer has an average pore size of 5 to 20 nm.

13. The conductive layer manufacturing method according to claim 4, wherein the porous layer has an average pore size of 5 to 20 nm.

14. The conductive layer manufacturing method according to claim 5, wherein the porous layer has an average pore size of 5 to 20 nm.

15. The conductive layer manufacturing method according to claim 3, wherein the porous layer has a thermal conductivity lower than that of the precursor layer.

16. The conductive layer manufacturing method according to claim 4, wherein the porous layer has a thermal conductivity lower than that of the precursor layer.

17. The conductive layer manufacturing method according to claim 5, wherein the porous layer has a thermal conductivity lower than that of the precursor layer.

18. The conductive layer manufacturing method according to claim 6, wherein the porous layer has a thermal conductivity lower than that of the precursor layer.

19. A printed circuit board having a conductive layer manufactured by the conductive layer manufacturing method according to claim 2.

20. A printed circuit board having a conductive layer manufactured by the conductive layer manufacturing method according to claim 3.
